(19) United States
(12) Patent Application Publication
(10) Pub. No.: US 2022/0036240 A1
(43) Pub. Date: Feb. 3, 2022

(54) MACHINE LEARNING DEVICE

(71) Applicant: Seiko Epson Corporation, Tokyo (JP)

(72) Inventor: Akihiko TSUNOYA, Okaya-shi (JP)

(21) Appl. No.: 17/387,702

(22) Filed: Jul. 28, 2021

(30) Foreign Application Priority Data
Jul. 31, 2020 (JP) 2020-130106

(51) Int. Cl. G06N 20/00; G06K 9/62

(52) U.S. Cl. CPC G06N 20/00; G06K 9/6256; G06K 9/6262

(57) ABSTRACT

A machine learning device includes: a data acquisition unit configured to acquire first data including shape data related to a target shape of a three-dimensional shaped object and shaping condition data related to a condition when the three-dimensional shaped object is shaped by the three-dimensional shaping device, and second data related to a deformation of the three-dimensional shaped object; a storage unit that stores learning data set including a plurality of the first data and a plurality of the second data; and a learning unit configured to learn a relationship between the first data and the second data by executing machine learning using the learning data set.

The present application is based on, and claims priority from JP Application Serial Number 2020-130106, filed Jul. 31, 2020, the disclosure of which is hereby incorporated by reference herein in its entirety.

### BACKGROUND

### 1. Technical Field

The present disclosure relates to a machine learning device.

### 2. Related Art

A technique is known in which a material including powdered metal or ceramic is laminated to shape a three-dimensional shaped object, and then the three-dimensional shaped object is sintered to increase strength. Since the three-dimensional shaped object shrinks due to sintering, the three-dimensional shaped object after the sintering may be distorted, cracked, warped, or the like. Regarding this problem, JP-T-2017-530027 discloses a technique in which a deformation of a three-dimensional shaped object is prevented by predicting a deformation amount of the three-dimensional shaped object due to heat using a finite element method, correcting an input geometry when the predicted deformation amount is not within an allowable range, and shaping the three-dimensional shaped object according to the corrected input geometry.

The deformation amount of the three-dimensional shaped object due to heat treatment is determined by combining various conditions, for example, a shape, a thickness, and a material of the three-dimensional shaped object, or a temperature, a temperature rise rate, and a time in the heat treatment of the three-dimensional shaped object. Therefore, it is difficult to make an accurate prediction by the technique of predicting the deformation amount of the three-dimensional shaped object using the finite element method as in JP-T-2017-530027. Such a problem is a common problem occurred not only when the powdered metal or the like is laminated and then sintered to manufacture the three-dimensional shaped object, but also when a plasticized thermoplastic resin is laminated to manufacture the three-dimensional shaped object.

### SUMMARY

According to an aspect of the present disclosure, a machine learning device is provided. The machine learning device includes: a data acquisition unit configured to acquire first data including shape data related to a target shape of a three-dimensional shaped object and shaping condition data related to a shaping condition when the three-dimensional shaped object is shaped by the three-dimensional shaping device, and second data related to a deformation of the three-dimensional shaped object; a storage unit that stores learning data set including a plurality of the first data and a plurality of the second data; and a learning unit configured to learn a relationship between the first data and the second data by executing machine learning using the learning data set.

### BRIEF DESCRIPTION OF THE DRAWINGS

FIG. 1 is an illustrative diagram showing a schematic configuration of a machine learning system.

FIG. 2 is an illustrative diagram showing a schematic configuration of a three-dimensional shaping device according to a first embodiment.

FIG. 3 is an illustrative diagram schematically showing a state in which the three-dimensional shaped object is divided into a plurality of layers.

FIG. 4 is an illustrative diagram schematically showing a state in which a layer is divided into a plurality of voxels.

FIG. 5 is a flowchart showing a method of manufacturing the three-dimensional shaped object.

FIG. 6 is a perspective view showing an example of the three-dimensional shaped object after a heat treatment step.

FIG. 7 is a flowchart showing a content of learning processing.

FIG. 8 is a flowchart showing a content of prediction processing.

FIG. 9 is a flowchart showing a content of correction processing.

FIG. 10 is an illustrative diagram showing an example of a distribution of a first part and a second part before and after correction.

FIG. 11 is an illustrative diagram showing a schematic configuration of a three-dimensional shaping device according to a second embodiment.

FIG. 12 is an illustrative diagram showing another example of a method of determining a shrinkage rate in correction processing.

### DESCRIPTION OF EXEMPLARY EMBODIMENTS

### A. First Embodiment

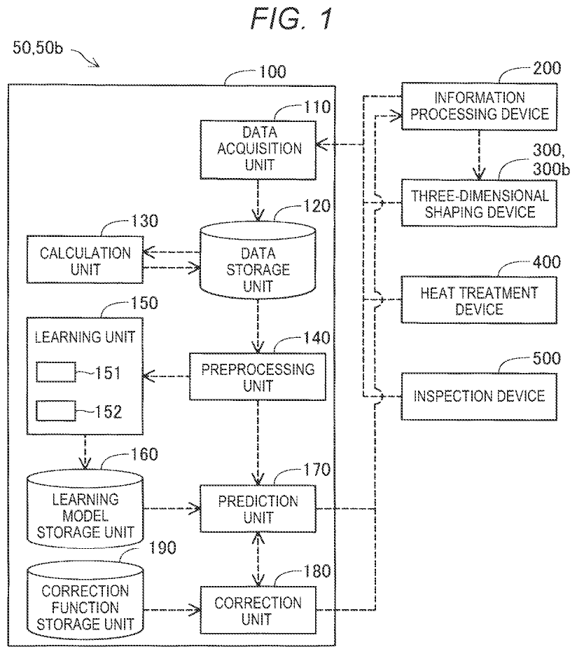

FIG. 1 is an illustrative diagram showing a schematic configuration of a machine learning system 50 according to a first embodiment. The machine learning system 50 includes a machine learning device 100, an information processing device 200, a three-dimensional shaping device 300, a heat treatment device 400, and an inspection device 500.

The machine learning device 100 is implemented by a computer including one or a plurality of processors, a main storage device, and an input and output interface that inputs a signal from the outside and outputs a signal to the outside. In the present embodiment, the machine learning device 100 generates a learning model by executing learning processing described later, predicts a manufacturing error of a three-dimensional shaped object using the learning model by executing prediction processing described later, and executes correction processing described later when the predicted manufacturing error is not within an allowable range. The machine learning device 100 may be implemented by a plurality of computers.

In the present embodiment, the machine learning device 100 includes a data acquisition unit 110, a data storage unit 120, a calculation unit 130, a preprocessing unit 140, a learning unit 150, a learning model storage unit 160, a prediction unit 170, a correction unit 180, and a correction function storage unit 190.

The data acquisition unit 110 acquires first data from the information processing device 200, the three-dimensional shaping device 300, and the heat treatment device 400 by wired communication or wireless communication. The first data includes shape data and shaping data described later. Further, the data acquisition unit 110 acquires second data from the inspection device 500 by the wired communication or the wireless communication. The second data includes measurement data described later.

The data storage unit 120 stores various data such as the first data or the second data. The calculation unit 130 uses the shape data included in the first data and the measurement data included in the second data to generate manufacturing error data described later. The preprocessing unit 140 generates a learning data set using the first data and the manufacturing error data. In the learning processing, the learning unit 150 executes machine learning using the learning data set, and generates the learning model. In the present embodiment, the learning unit 150 includes a reward calculation unit 151 and a value function update unit 152. The learning model storage unit 160 stores the learning model. In the prediction processing, the prediction unit 170 predicts the manufacturing error of the three-dimensional shaped object using the learning model. In the prediction processing, the correction unit 180 corrects the shaping data included in the first data according to a prediction result by the prediction unit 170. The correction function storage unit 190 stores a correction function used for correction of the shaping data by the correction unit 180.

The information processing device 200 is implemented by a computer including one or a plurality of processors, a main storage device, and an input and output interface that inputs a signal from the outside and outputs a signal to the outside. An input device such as a mouse or a keyboard and a display device such as a liquid crystal display are coupled to the information processing device 200. In the present embodiment, the information processing device 200 generates the shape data by three-dimensional CAD software installed in advance. The shape data indicates a target shape of the three-dimensional shaped object. The target shape means a shape that is targeted during manufacturing the three-dimensional shaped object. That is, when the three-dimensional shaped object is manufactured according to the target shape, the manufacturing error of the three-dimensional shaped object is zero. The shape data is transmitted to the machine learning device 100. Further, in the present embodiment, the information processing device 200 generates the shaping data by causing slicer software installed in advance to read the shape data. The shaping data is data indicating shaping conditions for shaping the three-dimensional shaped object by the three-dimensional shaping device 300, that is, various information for controlling the three-dimensional shaping device 300. The shaping data is transmitted to the machine learning device 100 and the three-dimensional shaping device 300. The shaping data may be called shaping condition data.

The three-dimensional shaping device 300 shapes the three-dimensional shaped object according to the shaping data. In the present embodiment, the three-dimensional shaping device 300 is a paste inkjet type three-dimensional shaping device that uses an inkjet technique to inject a paste-shaped liquid in which a powder material, a solvent, and a binder are mixed to shape a three-dimensional shaped object. A configuration of the three-dimensional shaping device 300 will be described later.

The heat treatment device 400 heat-treats the three-dimensional shaped object shaped by the three-dimensional shaping device 300. In the present embodiment, the heat treatment device 400 is a sintering furnace. The heat treatment device 400 sinters the three-dimensional shaped object according to predetermined heat treatment conditions. By the sintering, the three-dimensional shaped object shrinks, and strength of the three-dimensional shaped object increases. The heat treatment conditions include, for example, a heating time, a heating temperature, a heating rate, the number of times of heating, or the like in a heat treatment step.

The inspection device 500 measures a dimension of the three-dimensional shaped object after the heat treatment and generates the measurement data. In the present embodiment, the inspection device 500 is a three-dimensional measurement machine. In the present embodiment, the measurement data indicates the shape of the three-dimensional shaped object after the heat treatment. The measurement data may indicate an amount of distortion, an amount of warpage, a presence or absence of a crack, or the like of the three-dimensional shaped object after the heat treatment.

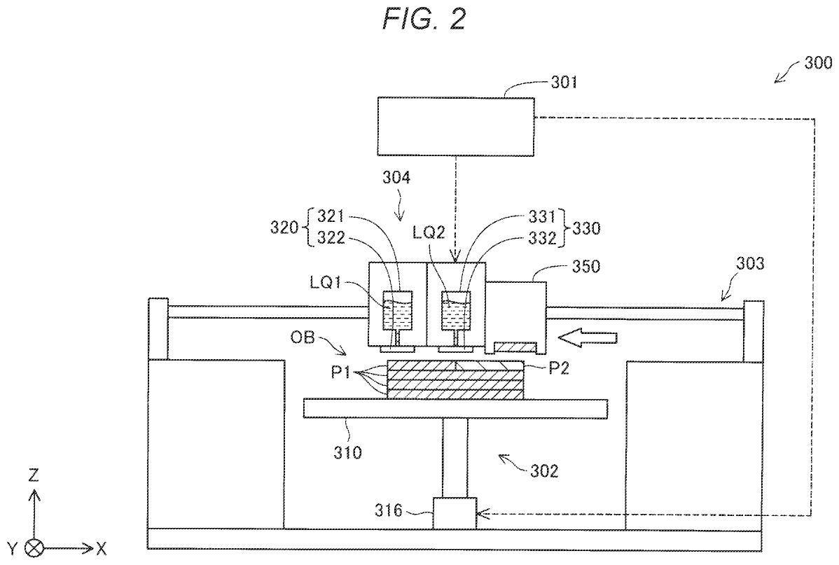

FIG. 2 is an illustrative diagram showing a schematic configuration of the three-dimensional shaping device 300. The three-dimensional shaping device 300 includes a control unit 301, a table unit 302, a moving mechanism 303, and a shaping unit 304. The control unit 301 is implemented by a computer including one or a plurality of processors, a main storage device, and an input and output interface that inputs a signal from the outside and outputs a signal to the outside. The control unit 301 controls the table unit 302, the moving mechanism 303, and the shaping unit 304 according to the shaping data supplied from the information processing device 200.

The table unit 302 includes a table 310 and an elevating mechanism 316 that moves the table 310 along a Z direction. In the present embodiment, the elevating mechanism 316 is implemented by an actuator that moves the table 310 along the Z direction under control of the control unit 301.

The moving mechanism 303 is provided above of the table unit 302. The moving mechanism 303 supports the shaping unit 304, and moves the shaping unit 304 relative to the table 310 along an X direction. In the present embodiment, the moving mechanism 303 is implemented by the actuator that moves the shaping unit 304 along the X direction under the control of the control unit 301.

The shaping unit 304 is disposed above the table unit 302. The shaping unit 304 includes a first material supply unit 320, a second material supply unit 330, and a curing energy supply unit 350. In the shaping unit 304, the first material supply unit 320, the second material supply unit 330, and the curing energy supply unit 350 are disposed in this order from a −X direction side.

The first material supply unit 320 supplies a first liquid LQ1, which is a paste-shaped liquid containing a powder material, a solvent, and a binder, onto the table 310. The first material supply unit 320 includes a first supply source 321 which is a supply source of the first liquid LQ1 and a first head 322 which supplies the first liquid LQ1 onto the table 310. In the present embodiment, the first supply source 321 is implemented by a tank for storing the first liquid LQ1. The first head 322 is implemented by a piezo-driven liquid injection head including a pressure chamber, a piezo element that changes a volume of the pressure chamber, and a plurality of nozzle holes communicating with the pressure chamber. The first head 322 is provided with the plurality of nozzle holes along a Y direction. The first head 322 reduces the volume of the pressure chamber by bending, by the piezo element, a side wall of the pressure chamber filled with the first liquid LQ1 supplied from the first supply source 321, and injects the first liquid LQ1 in an amount corresponding to a volume reduction amount of the pressure chamber from the nozzle holes.

The second material supply unit 330 supplies a second liquid LQ2, which is a paste-shaped liquid containing a powder material, a solvent, and a binder, onto the table 310. The second material supply unit 330 includes a second supply source 331 which is a supply source of the second liquid LQ2, and a second head 332 which supplies the second liquid LQ2 on the table 310. In the present embodiment, the second supply source 331 is implemented by a tank for storing the second liquid LQ2. The second head 332 is implemented by a piezo-driven liquid injection head including a pressure chamber, a piezo element that changes a volume of the pressure chamber, and a plurality of nozzle holes communicating with the pressure chamber. The second head 332 is provided with the plurality of nozzle holes along the Y direction. The second head 332 reduces the volume of the pressure chamber by bending, by the piezo element, a side wall of the pressure chamber filled with the second liquid LQ2 supplied from the second supply source 331, and injects the second liquid LQ2 in an amount corresponding to a volume reduction amount of the pressure chamber from the nozzle holes.

The powder material contained in the first liquid LQ1 and the second liquid LQ2 is a raw material for the three-dimensional shaped object. As the powder material, for example, a powder of a metal material such as a stainless steel, a steel other than the stainless steel, a pure iron, a titanium alloy, a magnesium alloy, a cobalt alloy, or a nickel alloy, or a powder of a ceramic material such as silicon dioxide, titanium dioxide, aluminum oxide, zirconium oxide, silicon nitride can be used. One type of these materials may be used as the powder material, or two or more types of these materials may be combined and used as the powder material. In the present embodiment, a stainless steel powder is used as the powder material contained in the first liquid LQ1 and the second liquid LQ2.

As the solvent contained in the first liquid LQ1 and the second liquid LQ2, an organic solvent, for example, water, alkylene glycol monoalkyl ethers such as ethylene glycol monomethyl ether, acetic acid esters such as ethyl acetate, aromatic hydrocarbons such as benzene, ketones such as methyl ethyl ketone, or alcohols such as ethanol can be used. One type of those solvents may be used as the solvent, or two or more types may be used in combination as the solvent.

As the binder contained in the first liquid LQ1 and the second liquid LQ2, a thermoplastic resin, a thermosetting resin, an X-ray curable resin, various photo-curable resins including a visible light curable resin that is cured by light in a visible light region, an ultraviolet curable resin, and an infrared curable resin, or the like can be used. One type of these resins may be used as the binder, or two or more types of these resins may be combined and used as the binder. In the present embodiment, a thermosetting resin is used as the binder contained in the first liquid LQ1 and the second liquid LQ2.

A particle density of the first liquid LQ1 is lower than a particle density of the second liquid LQ2. The particle density means a volume of the powder material per unit volume. By reducing the number of particles of the powder material per unit volume in each liquid LQ1 and LQ2, the particle density of each liquid LQ1 and LQ2 can be reduced. The particle density of each liquid LQ1 and LQ2 can also be reduced by increasing an average particle size of the powder material contained in each liquid LQ1 and LQ2. As the average particle size, for example, a median diameter can be used. In the present embodiment, the number of particles of the powder material per unit volume in the first liquid LQ1 is smaller than the number of particles of the powder material per unit volume in the second liquid LQ2. The average particle size of the powder material contained in the first liquid LQ1 is equal to the average particle size of the powder material contained in the second liquid LQ2.

The curing energy supply unit 350 applies energy for curing the binder to the binder contained in the first liquid LQ1 and the second liquid LQ2. In the present embodiment, the curing energy supply unit 350 is implemented by a heater. The solvent contained in the first liquid LQ1 and the second liquid LQ2 supplied on the table 310 is volatilized by heating from the curing energy supply unit 350, and the binder contained in the first liquid LQ1 and the second liquid LQ2 supplied on the table 310 is cured by heating from the curing energy supply unit 350. When an ultraviolet curable binder is used, the curing energy supply unit 350 may be implemented by an ultraviolet lamp.

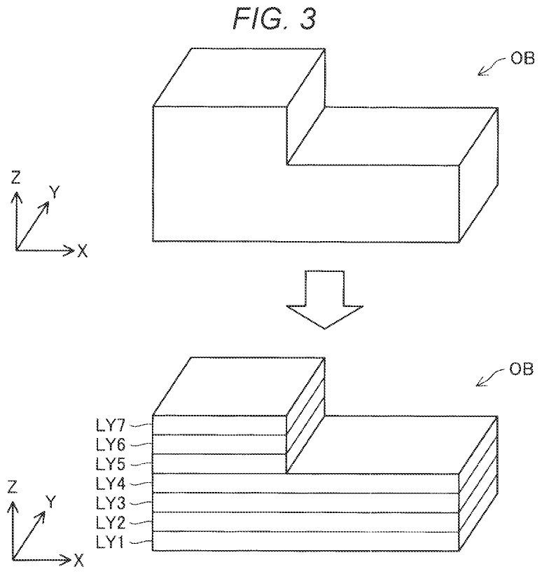

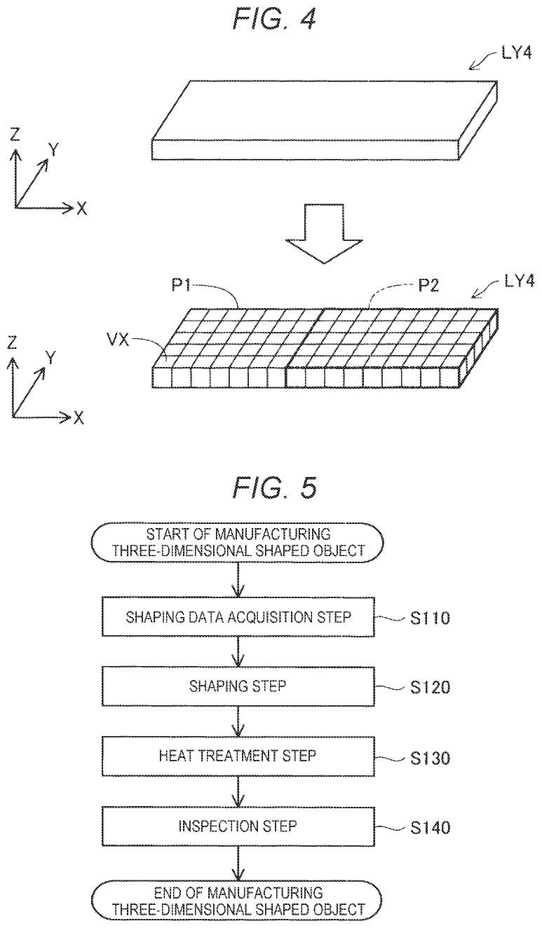

FIG. 3 is an illustrative diagram schematically showing a state in which a target shape of a three-dimensional shaped object OB is divided into a plurality of layers. FIG. 4 is an illustrative diagram schematically showing a state in which a layer of the three-dimensional shaped object OB is divided into a plurality of voxels VX. In the present embodiment, the target shape of the three-dimensional shaped object OB indicated by the shape data is expanded in size by the slicer software in consideration of the shrinkage rate due to heat treatment, and is divided into a plurality of layers each having a predetermined thickness. As an example, FIG. shows the state in which the target shape of the three-dimensional shaped object OB is divided into seven layers. The layers are called a first layer LY1, a second layer LY2, a third layer LY3, a fourth layer LY4, a fifth layer LY5, a sixth layer LY6, and a seventh layer LY7 in order from a −Z direction side. Further, in the present embodiment, each layer is divided into a plurality of cubic or rectangular parallelepiped voxels VX having a predetermined volume by the slicer software. As an example, FIG. 4 shows the state in which the fourth layer LY4 is divided into the plurality of voxels VX.

The shaping data includes information related to a position of each voxel VX and information related to a type of liquid used to shape each voxel VX. In the example shown in FIG. 4, in the fourth layer LY4, the second liquid LQ2 is used to shape each voxel VX in a region surrounded by an alternate long and short dash line, and the first liquid LQ1 is used to shape the other voxels VX. In the following description, a part of the three-dimensional shaped object OB that is shaped using the first liquid LQ1 is called a first part P1, and a part of the three-dimensional shaped object OB that is shaped using the second liquid LQ2 is called a second part P2.

FIG. 5 is a flowchart showing a method of manufacturing the three-dimensional shaped object OB in the present embodiment. The method of manufacturing the three-dimensional shaped object OB will be described by taking as an example a state in which the three-dimensional shaped object OB shown in FIGS. 3 and 4 is manufactured. First, in a shaping data acquisition step of step S110, the control unit 301 of the three-dimensional shaping device 300 acquires the shaping data from the information processing device 200.

In a shaping step of step S120, as shown in FIG. 2, the control unit 301 shapes the three-dimensional shaped object OB on the table 310 by controlling the shaping unit 304, the moving mechanism 303, and the elevating mechanism 316 of the table unit 302 according to the shaping data. In an initial state, the shaping unit 304 is disposed on the +X direction side of the table 310. The control unit 301 moves the shaping unit 304 in the −X direction by controlling the moving mechanism 303. While moving the shaping unit 304 in the −X direction, the control unit 301 supplies the first liquid LQ1 to the position where the first part P1 is shaped by controlling the first material supply unit 320, supplies the second liquid LQ2 to the position where the second part P2 is shaped by controlling the second material supply unit 330, and cures the binder contained in each liquid LQ1 and LQ2 supplied onto the table 310 by controlling the curing energy supply unit 350. By curing the binder, an n-th layer of the three-dimensional shaped object OB is formed. n is an optional natural number. After that, the control unit 301 returns the shaping unit 304 to a position on the +X direction side of the table 310 by controlling the moving mechanism 303, and lowers the table 310 by a thickness of the n-th layer by controlling the elevating mechanism 316. By repeating the above processing, the control unit 301 laminates an (n+1)th layer on the n-th layer, and shapes the three-dimensional shaped object OB.

In the heat treatment step of step S130 in FIG. 5, the three-dimensional shaped object OB is subjected to the heat treatment. In the present embodiment, the heat treatment device 400 degreases the binder from the three-dimensional shaped object OB, and further sinters the three-dimensional shaped object OB by heating the three-dimensional shaped object OB under predetermined heat treatment conditions. By the sintering, the three-dimensional shaped object OB shrinks, and strength of the three-dimensional shaped object OB increases.

In an inspection step of step S140, the inspection device 500 measures a dimension of the three-dimensional shaped object OB after the heat treatment step, and generates the measurement data. The measurement data is transmitted to the machine learning device 100. After the inspection step of step S140, the method of manufacturing the three-dimensional shaped object OB is completed.

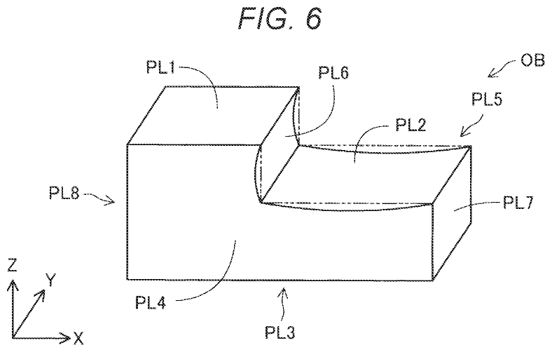

FIG. 6 is a perspective view showing an example of the three-dimensional shaped object OB after the heat treatment step. The three-dimensional shaped object OB shrinks due to the heat treatment step. In the three-dimensional shaped object OB, a part having a relatively high shrinkage rate and a part having a relatively low shrinkage rate may occur. Due to a large difference in the shrinkage rate in the three-dimensional shaped object OB, the three-dimensional shaped object OB may be distorted, warped, cracked, or the like. The three-dimensional shaped object OB shown in FIG. 6 has a first surface PL1, a second surface PL2, a third surface PL3, a fourth surface PL4, a fifth surface PL5, a sixth surface PL6, a seventh surface PL7, and an eighth surface PL8. In this example, the second surface PL2 and the sixth surface PL6 are distorted due to the relatively high shrinkage rate of the second surface PL2 and the sixth surface PL6. For such a problem, by adjusting a distribution of the particle density in the three-dimensional shaped object OB, it is possible to prevent the occurrence of distortion, warpage, and a crack in the three-dimensional shaped object OB. For example, by increasing a particle density of a part having a relatively high shrinkage rate, the shrinkage rate of the part can be decreased, and by decreasing a particle density of a part having a relatively low shrinkage rate, the shrinkage rate of the part can be increased. That is, by adjusting the arrangement of the first part P1 shaped using the first liquid LQ1 and the second part P2 shaped using the second liquid LQ2 in the three-dimensional shaped object OB, it is possible to prevent the occurrence of distortion, warpage, and a crack in the three-dimensional shaped object OB.

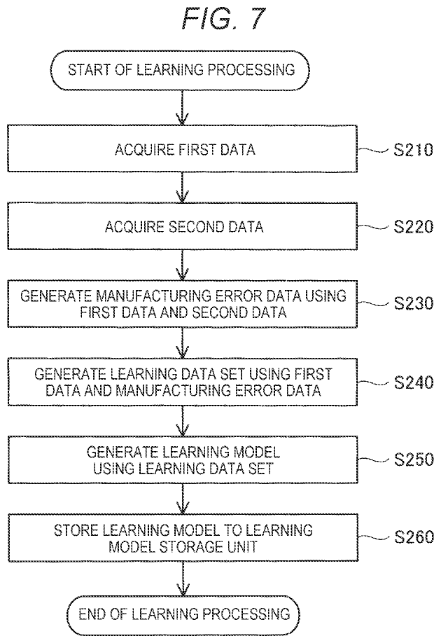

FIG. 7 is a flowchart showing a content of the learning processing in the present embodiment. This processing is executed by the machine learning device 100, for example, at a timing when the manufacture of one three-dimensional shaped object OB is completed. First, in step S210, the data acquisition unit 110 acquires the first data. The first data includes the shape data related to the target shape of the three-dimensional shaped object OB and the shaping data generated based on the shape data. In the present embodiment, the first data further includes heat treatment condition data representing the heat treatment conditions in the heat treatment step. The acquired first data is stored in the data storage unit 120.

In step S220, the data acquisition unit 110 acquires the second data. The second data includes the measurement data generated in the inspection step. In the present embodiment, the measurement data indicates the shape of the three-dimensional shaped object OB after the heat treatment step. The acquired second data is associated with the corresponding first data and stored in the data storage unit 120. An order of the processing in step S210 and the processing in step S220 may be reversed.

In step S230, the calculation unit 130 reads the shape data included in the first data and the measurement data included in the second data stored in the data storage unit 120, and generates the manufacturing error data representing an error between the dimension of the shape of the three-dimensional shaped object OB after the heat treatment step and the dimension of the target shape. The generated manufacturing error data is associated with the corresponding first data and stored in the data storage unit 120. In step S240, the preprocessing unit 140 reads the first data stored in the data storage unit 120 and the manufacturing error data associated with the first data, and generates the learning data set.

In step S250, the learning unit 150 reads the learning data set generated by the preprocessing unit 140, executes the machine learning, and generates the learning model. In step S260, the learning model storage unit 160 stores the learning model generated by the learning unit 150. After that, the machine learning device 100 ends this processing. The machine learning device 100 uses the learning data set including data on a plurality of three-dimensional shaped objects OB with different target shapes, shaping conditions, or heat treatment conditions to execute the machine learning and update the learning model by repeating this processing, for example, every time the manufacturing of one three-dimensional shaped object OB is completed.

An algorithm of the machine learning executed by the learning unit 150 in step S250 described above is not particularly limited, and for example, known algorithms such as supervised learning, unsupervised learning, reinforcement learning can be adopted. In the present embodiment, the learning unit 150 executes the reinforcement learning described later. The reinforcement learning is a method of repeating a cycle of executing a predetermined action in a current state while observing the current state of an environment in which a learning target exists and giving some kind of reward to the action by trial and error, and learning, as an optimal solution, a measure that maximizes a total reward.

An example of the algorithm of the reinforcement learning executed by the learning unit 150 will be described. The algorithm according to this example is known as Q-learning, and is a method of using a state s of an action subject and an action a that the action subject can select in the state s as independent variables, and learning a function Q (s, a) representing a value of the action when the action a is selected in the state s. The optimal solution is to select the action a in which the value function Q becomes the highest in the state s. By starting the Q-learning in a state where a correlation between the state s and the action a is unknown and repeating the trial and error that selects various actions a in any state s, the value function Q is repeatedly updated to approach the optimal solution. Here, when the environment, that is, the state s changes as a result of selecting the action a in the state s, a reward r, that is, a weighting of the action a can be acquired according to the change, learning is guided such that the action a is selected in which a higher reward r is acquired, so that the value function Q can approach the optimal solution in a relatively short time.

An update formula of the value function Q can be generally represented as the following formula (1).

$$Q ( {s}_{t} , {a}_{t} ) ← Q ( {s}_{t} , {a}_{t} ) + α ( {r}_{t + 1} + γ {max}_{a} Q ( {s}_{t + 1} , a ) - Q ( {s}_{t} , {a}_{t} ) ) \qquad ( 1 )$$

In the above formula (1), sₜ and aₜ are a state and an action at time t, respectively, and the state changes to sₜ₊₁ depending on the action aₜ. rₜ₊₁ is the reward acquired by changing the state from sₜ to sₜ₊₁. A term of maxQ means the Q when the action a, which is considered to be a maximum value Q at time t+1, is performed at the time t. α and γ are a learning coefficient and a discount rate, respectively, and are optionally set with 0<α≤1 and 0<γ≤1.

When the learning unit 150 executes the Q-learning, a state variable S, that is, the first data, and determination data D, that is, the manufacturing error data, correspond to the states of the update formula. An action of how to determine the distribution of the particle density with respect to the target shape of the three-dimensional shaped object OB in the current state, that is, an action of how to determine whether to supply the first liquid LQ1 or the second liquid LQ2 to the position of each voxel VX represented by the shaping data included in the first data in the current state corresponds to the action a of the update formula. A reward R acquired by the reward calculation unit 151 corresponds to the reward r of the update formula. Therefore, the value function update unit 152 repeatedly updates, by the Q-learning using the reward R, the function Q representing the value of the distribution of the particle density with respect to the target shape of the three-dimensional shaped object OB in the current state.

The reward R required by the reward calculation unit 151 can be a positive reward R, for example, when after determining the distribution of the particle density with respect to the target shape of the three-dimensional shaped object OB, the manufacturing error of the three-dimensional shaped object OB manufactured based on the determined distribution is smaller than the manufacturing error of the three-dimensional shaped object OB manufactured based on the distribution before the change, or the manufacturing error of the three-dimensional shaped object OB manufactured based on the determined distribution is within the allowable range. The reward R can be a negative reward R, for example, when after determining the distribution of the particle density with respect to the target shape of the three-dimensional shaped object OB, the manufacturing error of the three-dimensional shaped object OB manufactured based on the determined distribution is larger than the manufacturing error of the three-dimensional shaped object OB manufactured based on the distribution before the change or the manufacturing error of the three-dimensional shaped object OB manufactured based on the determined distribution exceeds the allowable range.

When the Q-learning is advanced using the reward R according to the manufacturing error of the manufactured three-dimensional shaped object OB, the learning is guided in a direction of selecting an action that gives a higher reward R, and according to a state of the environment that changes as a result of executing the selected action in the current state, that is, the state variable S and the determination data D, the value of an action value for the action performed in the current state, that is, the function Q is updated. By repeating this update, the function Q is rewritten such that the more appropriate the action, the larger the value. In this way, the correlation between the current state of an unknown environment and an action for the state is gradually clarified.

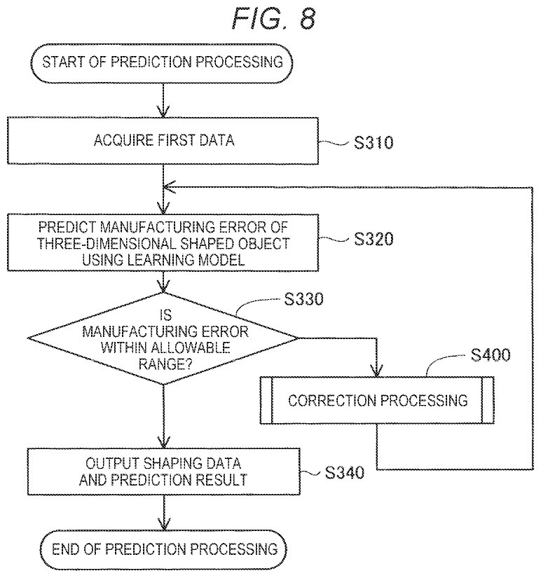

FIG. 8 is a flowchart showing a content of the prediction processing in the present embodiment. This processing is executed by the machine learning device 100 when a predetermined start command is supplied to the machine learning device 100. First, in step S310, the data acquisition unit 110 acquires the first data. The acquired first data is stored in the data storage unit 120.

Next, in step S320, the prediction unit 170 reads the first data stored in the data storage unit 120 and the learning model stored in the learning model storage unit 160, predicts the manufacturing error of the three-dimensional shaped object OB manufactured based on the first data, and generates prediction result data indicating the prediction result. The prediction unit 170 can predict the manufacturing error of the three-dimensional shaped object OB manufactured based on the first data by using the value Q calculated by reading the first data and the learning model. In the present embodiment, the prediction result data indicates the amount of the manufacturing error. The prediction result data may indicate the amount of distortion, the amount of warpage, the presence or absence of a crack, or the like of the three-dimensional shaped object OB manufactured based on the first data. The prediction result data may indicate a code indicating that the manufacturing error of the three-dimensional shaped object OB manufactured based on the first data is within the allowable range, or a code indicating that the manufacturing error of the three-dimensional shaped object OB manufactured based on the first data exceeds the allowable range.

In step S330, the prediction unit 170 determines whether the manufacturing error of the three-dimensional shaped object OB manufactured based on the first data is within the allowable range. The prediction unit 170 can determine whether the manufacturing error of the three-dimensional shaped object OB manufactured based on the first data is within the allowable range by comparing the manufacturing error indicated in the prediction result data with a preset tolerance of the manufacturing error.

When it is not determined in step S330 that the manufacturing error of the three-dimensional shaped object OB manufactured based on the first data is within the allowable range, in step S400, the correction unit 180 executes correction processing for correcting the shaping data included in the first data. A content of the correction processing will be described later. After that, the processing is returned to step S320, and the prediction unit 170 reads the first data in which the shaping data is corrected and the learning model, predicts the manufacturing error of the three-dimensional shaped object OB manufactured based on the first data in which the shaping data is corrected, and generates the prediction result data indicating the prediction result. The prediction unit 170 and the correction unit 180 repeat the processing of steps S400, S320, and S330 until it is determined in step S330 that the manufacturing error of the three-dimensional shaped object OB manufactured based on the first data is within the allowable range.

When it is determined in step S330 that the manufacturing error of the three-dimensional shaped object OB manufactured based on the first data is within the allowable range, in step S340, the machine learning device 100 ends this processing after outputting the shaping data and the prediction result data. In the present embodiment, the machine learning device 100 outputs the shaping data and the prediction result data to the information processing device 200. When the shaping data is corrected by the correction processing, the corrected shaping data and the prediction result data based on the corrected shaping data are output.

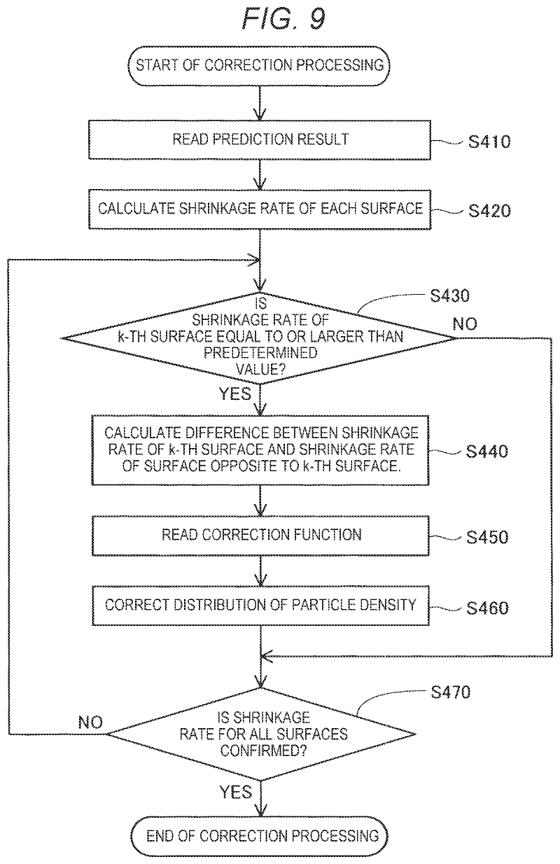

FIG. 9 is a flowchart showing the content of the correction processing in the present embodiment. First, in step S410, the correction unit 180 reads the prediction result data generated by the prediction unit 170. Next, in step S420, the correction unit 180 calculates a shrinkage rate of each surface of the three-dimensional shaped object OB using the prediction result data.

In step S430, the correction unit 180 determines whether a shrinkage rate of a k-th surface of the surfaces of the three-dimensional shaped object OB is equal to or larger than a predetermined value. k is any natural number. The correction unit 180 can determine whether the shrinkage rate of the k-th surface is equal to or larger than the predetermined value by comparing the shrinkage rate of the k-th surface with a preset threshold value. When it is determined in step S430 that the shrinkage rate of the k-th surface is equal to or greater than the predetermined value, in step S440, the correction unit 180 calculates a difference between the shrinkage rate of the k-th surface and a shrinkage rate of a surface opposite to the k-th surface. For example, as shown in FIG. 6, when the correction processing is executed for the three-dimensional shaped object OB having eight surfaces PL1 to PL8, in step S430, the correction unit 180 determines whether a shrinkage rate of the first surface PL1 is equal to or larger than a predetermined value, and when it is determined that the shrinkage rate of the first surface PL1 is equal to or larger than the predetermined value, in step S440, a difference between the shrinkage rate of the first surface PL1 and a shrinkage rate of the third surface PL3, which is the surface opposite to the first surface PL1, is calculated. In step S450, the correction unit 180 reads the correction function stored in the correction function storage unit 190. In the present embodiment, the correction function is a polynomial function or a rational function. The correction function represents, for example, a relationship between the manufacturing error and a volume of the second part P2 required to reduce the manufacturing error to the predetermined value or less. The correction function may represent a relationship between the amount of warpage and the volume of the second part P2 required to reduce the amount of warpage to a predetermined value or less. In step S460, the correction unit 180 corrects, based on the correction function, the distribution of the particle density indicated in the shaping data, in other words, information related to the type of liquid used to shape each voxel VX. On the other hand, when it is not determined in step S430 that the shrinkage rate of the k-th surface is equal to or larger than the predetermined value, the correction unit 180 skips the processing from step S440 to step S460.

After that, in step S470, the correction unit 180 determines whether confirmation of the shrinkage rate in step S430 is executed for all surfaces. The correction unit 180 repeats the processing from step S430 to step S470 until it is determined that the confirmation of the shrinkage rate in step S430 is executed for all surfaces. For example, in the three-dimensional shaped object OB shown in FIG. 6, after the processing from step S430 to step S460 for the first surface PL1 is executed, the correction unit 180 returns the processing to step S430 and determines whether the shrinkage rate of the second surface PL2 is equal to or larger than the predetermined value. When it is determined that the confirmation of the shrinkage rate in step S430 is executed for all surfaces, the correction unit 180 ends the processing. After that, as shown in FIG. 8, the processing of step S320 is executed using the corrected shaping data.

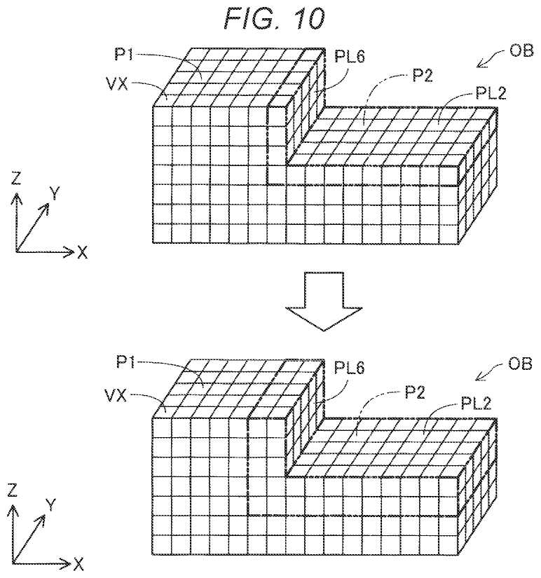

FIG. 10 is an illustrative diagram showing an example of the distribution of the first part P1 and the second part P2 before and after the correction. Compared to the distribution before the correction shown on an upper side of FIG. 10, in the distribution after the correction shown on a lower side of FIG. 10, in a peripheral portion of the second surface PL2 and a peripheral portion of the sixth surface PL6 which have a relatively large shrinkage rate, by changing the voxel VX shaped using the first liquid LQ1 to the voxel VX shaped using the second liquid LQ, a range of the second part P2 shaped using the second liquid LQ is expanded. Therefore, the variation in the shrinkage rate in the three-dimensional shaped object OB is prevented after the correction as compared with the case before the correction.

According to the machine learning device 100 in the present embodiment described above, in the learning processing, the learning unit 150 uses the learning data set generated based on the first data and the second data to generate the learning model that can predict the manufacturing error of the three-dimensional shaped object OB, and in the prediction processing, the prediction unit 170 predicts whether the manufacturing error of the three-dimensional shaped object OB is within the allowable range using the learning model, and outputs the prediction result data indicating the prediction result. Further, in the present embodiment, when the manufacturing error of the three-dimensional shaped object OB predicted by the prediction unit 170 exceeds the allowable range, the correction unit 180 corrects the distribution of the particle density in the three-dimensional shaped object OB indicated by the shaping data by using the correction function represented by the polynomial function or the rational function, and outputs the corrected shaping data. Therefore, by manufacturing the three-dimensional shaped object OB using the corrected shaping data, it is possible to prevent the manufacturing error of the three-dimensional shaped object OB from exceeding the allowable range.

Further, in the present embodiment, the learning data set used to generate the learning model includes the shaping data indicating the position of the first part P1 which is shaped using the first liquid LQ1 and the position of the second part P2 which is shaped using the second liquid LQ2 which has a higher particle density than the first liquid LQ1, in the three-dimensional shaped object OB. Therefore, it is possible to generate the learning model that can predict the manufacturing error of the three-dimensional shaped object OB according to the distribution of the particle density in the three-dimensional shaped object OB.

Further, in the present embodiment, the learning data set used to generate the learning model includes the heat treatment condition data. Therefore, it is possible to generate the learning model that can predict the manufacturing error of the three-dimensional shaped object OB according to the heat treatment conditions in the heat treatment step.

### B. Second Embodiment

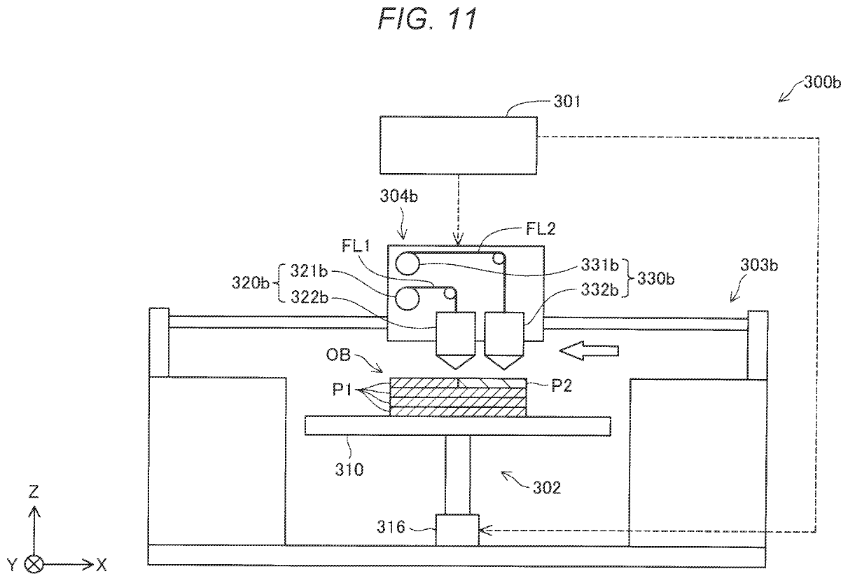

FIG. 11 is an illustrative diagram showing a schematic configuration of a three-dimensional shaping device 300b in a second embodiment. A machine learning system 50b in the second embodiment is different from the first embodiment in that the machine learning system 50b is provided with the fused deposition modeling (FDM) type three-dimensional shaping device 300b instead of the paste inkjet type three-dimensional shaping device. Other configurations are the same as those of the first embodiment shown in FIG. 1 unless otherwise specified.

As shown in FIG. 11, a shaping unit 304b includes a first material supply unit 320b and a second material supply unit 330b. In the present embodiment, the shaping unit 304b does not include the curing energy supply unit 350 shown in FIG. 2.

The first material supply unit 320b melts a first filament FL1 that is a wire-shaped material filament containing a powder material and a thermoplastic resin to generate a paste-shaped first molten material, and supplies the first molten material in a table shape. The term “melt” means not only that the thermoplastic material is heated to a temperature equal to or higher than a melting point and liquefied, but also that the thermoplastic material is heated to a temperature equal to or higher than a glass transition point and softened, thereby exhibiting the fluidity. The first material supply unit 320b includes a first supply source 321b that is a supply source of the first filament FL1, and a first head 322b that melts the first filament FL1 and supplies the first filament FL1 onto the table 310. In the present embodiment, the first supply source 321b is implemented by a reel on which the first filament FL1 is wound. The first head 322b includes a heater that melts the first filament FL1 supplied from the first supply source 321b to generate the first molten material, and an extruder having a nozzle for discharging the first molten material.

The second material supply unit 330b melts a second filament FL2 that is a wire-shaped material filament containing a powder material and a thermoplastic resin to generate a paste-shaped second molten material, and supplies the second molten material in a table shape. The second material supply unit 330b includes a second supply source 331b that is a supply source of the second filament FL2, and a second head 332b that melts the second filament FL2 and supplies the second filament FL2 onto the table 310. In the present embodiment, the second supply source 331b is implemented by a reel on which the second filament FL2 is wound. The second head 332b includes a heater that melts the second filament FL2 supplied from the second supply source 331b to generate the second molten material, and an extruder having a nozzle for discharging the second molten material.

The types of powder materials contained in the first filament FL1 and the second filament FL2 are the same as those in the first embodiment. As the thermoplastic resin contained in the first filament FL1 and the second filament FL2, for example, an ABS resin, polypropylene, a polylactic acid, or the like can be used. A particle density of the first filament FL1 is lower than a particle density of the second filament FL2. In other words, a particle density of the first molten material is lower than a particle density of the second molten material.

In the present embodiment, a moving mechanism 303b moves the shaping unit 304 relative to the table 310 along the X and Y directions. In the present embodiment, the moving mechanism 303 includes an actuator that moves the shaping unit 304 along the X direction under the control of the control unit 301, and an actuator that moves the shaping unit 304 along the Y direction under the control of the control unit 301.

In the present embodiment, in the shaping step shown in step S120 of FIG. 5, the control unit 301 shapes the three-dimensional shaped object OB on the table 310 by controlling the shaping unit 304, the moving mechanism 303, and the elevating mechanism 316 of the table unit 302 according to the shaping data. While the control unit 301 moves the shaping unit 304 along the X and Y directions by controlling the moving mechanism 303, the control unit 301 supplies, by controlling the first material supply unit 320b, the first molten material to the position where the first part P1 is shaped, and supplies, by controlling the second material supply unit 330, the second molten material to the position where the second part P2 is shaped. The thermoplastic resin contained in the first molten material and the thermoplastic resin contained in the second molten material are cooled and cured on the table 310 to form a n-th layer of the three-dimensional shaped object OB. After that, the control unit 301 lowers the table 310 by a thickness of the n-th layer by controlling the elevating mechanism 316, and then repeats the above-described processing to laminate an (n+1)th layer on the n-th layer to shape the three-dimensional shaped object OB.

According to the machine learning system 50b in the present embodiment described above, the three-dimensional shaped object OB is shaped by the FDM type three-dimensional shaped object device 300b. In the FDM. type three-dimensional shaping device 300b, the particle density of the first molten material can be made higher than the particle density of the first liquid LQ1 of the first embodiment, and the particle density of the second molten material can be made higher than the particle density of the second liquid LQ2 of the first embodiment. Therefore, the shrinkage rate of the entire three-dimensional shaped object OB can be made smaller than that in the first embodiment, and the three-dimensional shaped object OB can be shaped with higher dimensional accuracy.

### C. Other Embodiments

(C1) In the machine learning device 100 of each of the above embodiments, the algorithm of the machine learning executed by the learning unit 150 in the learning processing is the reinforcement learning. On the other hand, the algorithm of the machine learning executed by the learning unit 150 in the learning processing may be the supervised learning. For example, in the learning processing, the learning unit 150 may execute the supervised learning using the learning data set including a normal label indicating that the manufacturing error of the three-dimensional shaped object OB is within the allowable range and an abnormal label indicating that the manufacturing error of the three-dimensional shaped object OB exceeds the allowable range, and may generate a discriminant boundary between normal data and abnormal data as the learning model. In this case, in the prediction processing, the prediction unit 170 uses the learning model to determine whether the read first data belongs to the normal data or the abnormal data, in other words, predict whether the manufacturing error of the three-dimensional shaped object OB manufactured based on the read first data is within the allowable range.

(C2) In the machine learning device 100 of each of the above embodiments, the algorithm of the machine learning executed by the learning unit 150 in the learning processing is the reinforcement learning. On the other hand, the algorithm of the machine learning executed by the learning unit 150 in the learning processing may be the unsupervised learning. For example, in the learning processing, the learning unit 150 may execute the unsupervised learning using the learning data set implemented by the data about the three-dimensional shaped object OB whose manufacturing error is within the allowable range, and may generate a distribution of the data about the three-dimensional shaped object OB whose manufacturing error is within the allowable range as the learning model. In this case, in the prediction processing, the prediction unit 170 can use the learning model to calculate how much the read data deviates from the data about the three-dimensional shaped object OB whose manufacturing error is within the allowable range, and calculate an abnormality as the prediction result.

(C3) In the three-dimensional shaping device 300b of the first embodiment described above, the first liquid LQ1 and the second liquid LQ2 contain a powder material. On the other hand, the second liquid LQ2 may not contain the powder material. In this case, by only supplying the first liquid LQ1 to the part where the particle density is relatively high in the three-dimensional shaped object OB, and supplying the first liquid to the part where the particle density is relatively low and then further supplying the second liquid LQ2, the distribution of the particle density in the three-dimensional shaped object OB can be adjusted.

(C4) In each of the above-described embodiments, the machine learning systems 50, 50b each include one three-dimensional shaping device 300, 300b. On the other hand, the machine learning systems 50, 50b may each include a plurality of three-dimensional shaping devices 300, 300b. The first data acquired by the data acquisition unit 110 of the machine learning device 100 may include data acquired from the plurality of three-dimensional shaping devices 300, 300b. Deformation of the three-dimensional shaped object OB can be predicted depending on which of the plurality of three-dimensional shaped object devices 300, 300b is used to shape the three-dimensional shaped object OB.

(C5) In each of the above-described embodiments, the first data acquired by the data acquisition unit 110 of the machine learning device 100 includes the heat treatment condition data. On the other hand, the first data may not include the heat treatment condition data.

(C6) In each of the above-described embodiments, the machine learning device 100 includes the prediction unit 170. On the other hand, the machine learning device 100 may not include the prediction unit 170. For example, the learning model generated by the learning unit 150 may be moved to another device having a function of the prediction unit 170 by using wired communication, wireless communication, or an information recording medium, and the prediction processing shown in FIG. 7 may be executed on the other device.

(C7) In each of the above-described embodiments, the machine learning device 100 includes the correction unit 180. On the other hand, the machine learning device 100 may not include the correction unit 180. After step S320 of the prediction processing shown in FIG. 8, the prediction unit 170 may skip the processing of step S330 and output only the prediction result data in step S340. In this case, since the user can refer to the output prediction result data, when the prediction result is not preferable, for example, the shaping data can be modified on the information processing device 200 to adjust the distribution of the particle density.

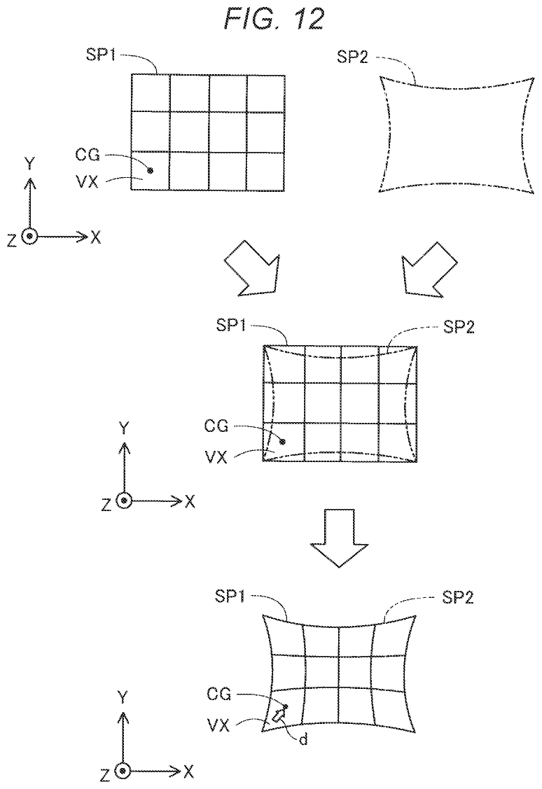

(C8) FIG. 12 is an illustrative diagram showing another example of a method of determining a shrinkage rate in the correction processing. In step S430 of the correction processing shown in FIG. 9, the correction unit 180 may determine whether the shrinkage rate is equal to or larger than the predetermined value based on a displacement amount of each voxel VX. For example, as shown in FIG. 12, the correction unit 180 superimposes a shape SP1 of the three-dimensional shaped object divided into the plurality of voxels VX on a shape SP2 of the three-dimensional shaped object indicated in the measurement data, and may detect a ridge line or a curved surface from the shape SP2 of the three-dimensional shaped object indicated in the measurement data, and may detect, from the shape SP1 of the three-dimensional shaped object divided into the plurality of voxels VX, a ridge line or a curved surface corresponding to the ridge line or the curved surface detected from the shape SP2 of the three-dimensional shaped object indicated in the measurement data. The correction unit 180 deforms the shape SP1 of the three-dimensional shaped object divided into the plurality of voxels VX, such that dividing lines are evenly spaced and the ridge line or the curved surface detected from the shape SP2 of the three-dimensional shaped object indicated in the measurement data and the ridge line or the curved surface detected from the shape SP1 of the three-dimensional shaped object divided into the plurality of voxels VX are superimposed. The correction unit 180 may calculate a displacement amount d of a center point CG of each voxel VX before and after the deformation, and when the displacement amount d is equal to or larger than a predetermined value, the correction unit 180 may determine that the shrinkage rate is equal to or larger than the predetermined value. Alternatively, the correction unit 180 may superimpose the shape SP1 of the three-dimensional shaped object divided into the plurality of voxels VX on the shape SP2 of the three-dimensional shaped object represented by the measurement data, calculate a thickness of each region of the three-dimensional shaped object indicated in the measurement data, determine a thickness of each voxel VX by dividing the calculated thickness of each region by the number of voxels VX in each region, deform each voxel VX so as to have a determined thickness, and calculate a displacement amount of a center point of each voxel VX before and after the deformation. In these cases, the correction unit 180 can correct the information related to the type of liquid used for shaping each voxel VX, even if the three-dimensional shaped object has a complicated shape including a curved surface.

### D. Other Aspects

The present disclosure is not limited to the above-described embodiments, and can be implemented in various aspects without departing from the spirit of the present disclosure. For example, the present disclosure can be implemented in the following aspects. In order to solve a part of or all of problems of the present disclosure, or to achieve a part of or all of effects of the present disclosure, technical features in the above-described embodiments corresponding to technical features in the following aspects can be replaced or combined as appropriate. Further, when the technical features are not described as essential in the present description, the technical features can be appropriately deleted.

(1) According to an aspect of the present disclosure, a machine learning device is provided. The machine learning device includes: a data acquisition unit configured to acquire first data including shape data related to a target shape of a three-dimensional shaped object and shaping condition data related to a shaping condition when the three-dimensional shaped object is shaped by the three-dimensional shaping device, and second data related to a deformation of the three-dimensional shaped object; a storage unit that stores learning data set including a plurality of the first data and a plurality of the second data; and a learning unit configured to learn a relationship between the first data and the second data by executing machine learning using the learning data set.

According to the machine learning device of the aspect, the learning unit can generate a learning model that can predict deformation of the three-dimensional shaped object by the machine learning.

(2) In the machine learning device of the aspect, the shaping condition data may include data, as the shaping condition, related to a density of particles contained in a material used for shaping the three-dimensional shaped object.

According to the machine learning device of the aspect, the learning unit can generate the learning model that can predict the deformation of the three-dimensional shaped object according to the density of particles contained in the material of the three-dimensional shaped object.

(3) In the machine learning device of the aspect, the first data may include heat treatment condition data related to a heat treatment condition for the three-dimensional shaped object.

According to the machine learning device of the aspect, the deformation of the three-dimensional shaped object can be predicted even when the heat treatment conditions are changed.

(4) In the machine learning device of the aspect, the learning unit may be configured to execute at least one of supervised learning, unsupervised learning, and reinforcement learning as the machine learning.

According to the machine learning device of the aspect, the learning model can be generated by the at least one of the supervised learning, the unsupervised learning, and the reinforcement learning.

(5) In the machine learning device of the aspect, the data acquisition unit may be configured to acquire a plurality of the shaping condition data from the three-dimensional shaping device.

According to the machine learning device of the aspect, the deformation of the three-dimensional shaped object can be predicted depending on which of the plurality of three-dimensional shaped object devices is used to shape the three-dimensional shaped object.

(6) The machine learning device of the aspect may include a prediction unit configured to predict the deformation of the three-dimensional shaped object using a learning model generated by the machine learning of the learning unit.

According to the machine learning device of the aspect, the deformation of the three-dimensional shaped object can be predicted using the learning model. Therefore, when the prediction result is not preferable, the user can change the shaping condition data.

(7) The machine learning device of the aspect may include a correction unit configured to correct the shaping condition data according to a prediction result by the prediction unit and output the corrected shaping condition data.

According to the machine learning device of the aspect, the correction unit corrects and outputs the shaping condition data according to the prediction result. Therefore, by manufacturing the three-dimensional shaped object using the output shaping condition data after the correction, the three-dimensional shaped object can be manufactured with high dimensional accuracy.

(8) In the machine learning device of the aspect, the correction unit may be configured to correct the shaping condition data using at least one of a polynomial function and a rational function.

According to the machine learning device of the aspect, the correction unit can correct the shaping condition data using at least one of a polynomial function and a rational function.

The present disclosure can also be implemented in various aspects other than the machine learning device. For example, the present disclosure can be implemented in aspects of the machine learning system, a method of predicting the manufacturing error of the three-dimensional shaped object, or the like.

What is claimed is:

1. A machine learning device, comprising:
a data acquisition unit configured to acquire first data including shape data related to a target shape of a three-dimensional shaped object and shaping condition data related to a shaping condition when the three-dimensional shaped object is shaped by a three-dimensional shaping device, and second data related to a deformation of the three-dimensional shaped object;
a storage unit that stores learning data set including a plurality of the first data and a plurality of the second data; and
a learning unit configured to learn a relationship between the first data and the second data by executing machine learning using the learning data set.

2. The machine learning device according to claim 1, wherein
the shaping condition data includes data, as the shaping condition, related to a density of particles contained in a material used for shaping the three-dimensional shaped object.

3. The machine learning device according to claim 1, wherein
the first data includes heat treatment condition data related to a heat treatment condition for the three-dimensional shaped object.

4. The machine learning device according to claim 1, wherein
the learning unit is configured to execute at least one of supervised learning, unsupervised learning, and reinforcement learning as the machine learning.

5. The machine learning device according to claim 1, wherein
the data acquisition unit is configured to acquire a plurality of the shaping condition data from the three-dimensional shaping device.

6. The machine learning device according to claim 1, further comprising:
a prediction unit configured to predict the deformation of the three-dimensional shaped object using a learning model generated by the machine learning of the learning unit.

7. The machine learning device according to claim 6, further comprising:
a correction unit configured to correct the shaping condition data according to a prediction result by the prediction unit and output the corrected shaping condition data.

8. The machine learning device according to claim 7, wherein
the correction unit is configured to correct the shaping condition data using at least one of a polynomial function and a rational function.
